(19) United States
(12) Patent Application Publication
(10) Pub. No.: US 2008/0173860 A1
(43) Pub. Date: Jul. 24, 2008

(54) Phase change memory device and method of fabricating the same

(75) Inventors: Woong-chul Shin, Yongin-si (KR); Ki-joon Kim, Yongin-si (KR); Ji-hyun Hur, Yongin-si (KR); Hyo-sug Lee, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 12/007,014

(22) Filed: Jan. 4, 2008

(30) Foreign Application Priority Data
Jan. 5, 2007 (KR) 10-2007-0001696

(51) Int. Cl. H01L 45/00

(52) U.S. Cl. 257/3; 438/102; 257/E45.002

(57) ABSTRACT

Provided are a phase change memory device and a method of fabricating the same. The phase change memory device including a phase change layer in a storage node thereof includes: a bottom electrode; a bottom electrode contact layer formed of a phase change material disposed on the bottom electrode; a first phase change layer having a smaller width than the bottom electrode contact layer, disposed on the bottom electrode contact layer; a second phase change layer having a larger width than the first phase change layer, disposed on the first phase change layer; and a upper electrode disposed on the second phase change layer.

### CROSS-REFERENCE TO RELATED PATENT APPLICATIONS

This application claims the benefit of Korean Patent Application No. 10-2007-0001696, filed on Jan. 5, 2007, in the Korean Intellectual Property Office, the disclosure of which is incorporated herein in its entirety by reference.

### BACKGROUND OF THE INVENTION

1. Field of the Invention

The present invention relates to a semiconductor memory device and a method of fabricating the same, and more particularly, to a phase change memory device including a bottom electrode contact (BEC) layer formed of a phase change material so as to prevent deterioration and heat loss in a programming area thereof and a method of fabricating the same.

2. Description of the Related Art

As information based industries develop, demand for processing large amounts of information is increasing. As a result, demand for information storage media capable of storing large amounts of information is also increasing. In response to such an increasing demand for such information storage media, research into small-sized information storage media which can store information quickly is being performed and thus, now, various kinds of information storage devices have been developed.

For example, a phase-change memory device (PRAM), which is regarded as being a next-generation memory device, is being studied. In general, a phase change memory device includes a phase change layer formed of a phase change material, such as a chalcogenide material. The phase change material has a very different resistance when it is in a crystalline phase from when it is in an amorphous phase. That is, a phase change material can have two phases, which can be differentiated from each other according to their resistances. The phase change material reversibly changes according to temperature. Until now, many phase change materials have been developed. For example, GST (Ge₂Sb₂Te₅) is conventionally used as a phase change material.

FIGS. 1A and 1B are sectional views of conventional phase change memory devices. Specifically, FIG. 1A is a sectional view of a T-shaped phase change memory device, and FIG. 1B is a sectional view of a confined-structure phase change memory device.

Referring to FIG. 1A, a bottom electrode contact (BEC) layer 13 is formed on a bottom electrode 12. A first insulating layer 11a is formed on side surfaces of the bottom electrode 12 and a second insulating layer 11b is formed on side surfaces of the BEC layer 13. A phase change layer 14 is formed on the BEC layer 13 and the second insulating layer 11b, and a contact layer 15 and a upper electrode 16 are sequentially formed on the phase change layer 14.

Referring to FIG. 1B, a BEC layer 103 is formed on a bottom electrode 102. The BEC layer 103 may have a smaller width than the bottom electrode 102. A first insulating layer 101a is formed on side surfaces of the bottom electrode 102, and a second insulating layer 101b is formed on side surfaces of the BEC layer 103. A phase change layer 104 is formed on the BEC layer 103 and the second insulating layer 101b. A contact layer 105 and a upper electrode 106 are sequentially formed on the phase change layer 104. The phase change memory device illustrated in FIG. 1B is different from the phase change memory device illustrated in FIG. 1A, in that the BEC layer 103 is formed to a half of the thickness of the second insulating layer 101b and the phase change layer 104 is formed within the second insulating layer 101b.

In a phase change memory, reversible phase changes between a crystalline phase and an amorphous phase occur due to Joule heat generated in a contact area between the phase change layer and a bottom electrode when a current is provided through bottom and upper electrodes, to record information. Specifically, an area in which the phase change occurs intensively is called a program volume (PV) area. Reference numerals 17 of FIG. 1A and 107 of FIG. 1B denote PV areas.

A phase change layer material used in a phase change memory device, for example, GST should retain its properties to obtain a reliable phase change memory device. A phase change memory device has endurance defects due to several reasons. For example, when the phase change is repeated, adhesion defects can occur at the interface between a PV area and a BEC layer. In addition, when the phase change occurs, a specific resistance may occur at the interface between the phase change layer and the BEC layer, thereby causing heat loss and changing the PV area. Such problems cannot be solved completely since the PV area is formed at the interface between the phase change layer and the BEC layer as illustrated in FIGS. 1A and 1B. Currently, many studies to solve these problems are being carried out, but solutions thereto have not yet been obtained.

### SUMMARY OF THE INVENTION

The present invention provides a phase change memory device requiring a small amount of applied current by preventing deterioration and heat loss of the phase change memory device at an interface between a phase change layer and a bottom electrode contact (BEC) layer when the phase change is repeated.

According to an aspect of the present invention, there is provided a phase change memory device including a phase change layer in a storage node, including: a bottom electrode; a bottom electrode contact layer formed of a phase change material disposed on the bottom electrode; a first phase change layer having a smaller width than the bottom electrode contact layer, disposed on the bottom electrode contact layer; a second phase change layer having a larger width than the first phase change layer, disposed on the first phase change layer; and a upper electrode disposed on the second phase change layer.

The phase change memory device may further include a first insulating layer formed on side surfaces of the bottom electrode and the bottom electrode contact layer; and a second insulating layer formed on side surfaces of the first phase change layer.

The bottom electrode contact layer, the first phase change layer, and the second phase change layer may be formed of the same kind of phase change material.

The bottom electrode contact layer, the first phase change layer, and the second phase change layer may be formed of Ge₂Sb₂Te₅ (GST) that is a phase change material.

A program value area may be formed at the interface between the bottom electrode contact layer and the first phase change layer.

The phase change memory device may further include a Ti or TiN thin layer interposed between the bottom electrode and the bottom electrode contact layer.

The phase change memory device may further include a semiconductor substrate having a source region and a drain region; a gate insulating layer contacting one of the source region and the drain region, disposed on the semiconductor substrate; a gate electrode layer disposed on the gate insulating layer; and a contact plug formed between the drain region and the bottom electrode.

According to another aspect of the present invention, there is provided a method of fabricating a phase change memory device including a phase change layer in a storage node, the method including: (a) opening a first insulating layer, and forming and planarizing a bottom electrode and a bottom electrode contact layer; (b) forming a second insulating layer on the first insulating layer and the bottom electrode, and forming a hole having a smaller width than the bottom electrode to expose the bottom electrode; (c) forming a phase change layer in the hole and on the second insulating layer; (d) forming a upper electrode on the phase change layer.

The process (a) includes: forming a first insulating layer; opening the first insulating layer, and forming the bottom electrode and etching a top portion of the bottom electrode; doping a phase change material on the bottom electrode; and planarizing the phase change material to form a bottom electrode contact layer.

### BRIEF DESCRIPTION OF THE DRAWINGS

The above and other features and advantages of the present invention will become more apparent by describing in detail exemplary embodiments thereof with reference to the attached drawings in which:

FIGS. 1A and 1B are sectional views of conventional phase change memory devices;

FIG. 2 is a sectional view of a phase change memory device according to an embodiment of the present invention, illustrating a storage node area;

FIG. 3 is a sectional view of the phase change memory device of FIG. 2 connected to a transistor;

FIGS. 4A through 4G are sectional views illustrating a method of fabricating a phase change memory device according to an embodiment of the present invention; and

FIGS. 5A and 5B are pictorial views illustrating results of measuring temperatures of respective areas when a current is provided through bottom and upper electrodes of a phase change memory device according to an embodiment of the present invention.

### DETAILED DESCRIPTION OF THE INVENTION

The present invention will now be described more fully with reference to the accompanying drawings, in which exemplary embodiments of the invention are shown. In the drawings, the thicknesses of layers and regions are exaggerated for clarity.

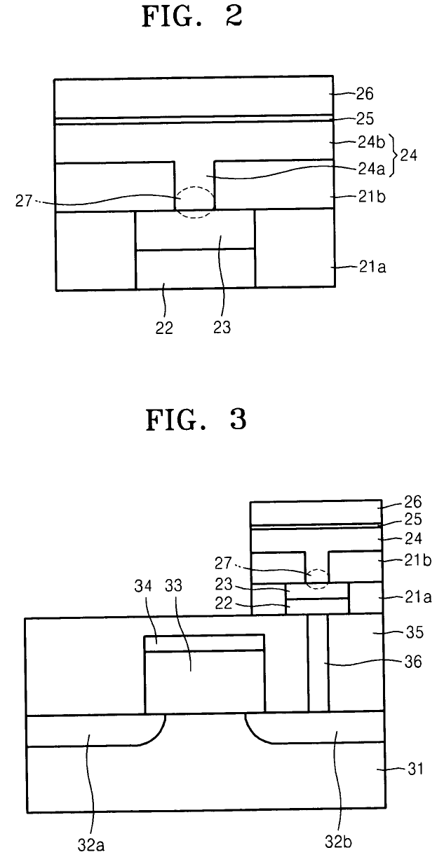

FIG. 2 is a sectional view illustrating a storage node area of a phase change memory device according to an embodiment of the present invention.

Referring to FIG. 2, a bottom electrode contact (BEC) layer 23 is formed on a bottom electrode 22. The BEC layer 23 may have a width equal or similar to the bottom electrode 22. A first insulating layer 21a may be formed on side surfaces of the bottom electrode 22 and side surfaces of the BEC layer 23. A first phase change layer 24a and a second insulating layer 21b are formed on the BEC layer 23. A width of the first phase change layer 24a may be relatively smaller than a width of the BEC layer 23. A second phase change layer 24b is formed on the first phase change layer 24a and the second insulating layer 21b, and a contact layer 25 and a upper electrode 26 are sequentially formed on the second phase change layer 24b. If required, a Ti/TiN thin layer that is a barrier metal (BM) layer can be further formed between the bottom electrode 22 and the BEC layer 23.

In the phase change device according to the current embodiment of the present invention, the BEC layer 23 and the first phase change layer 24a may be formed of the same kind of material. For example, the BEC layer 23, the first phase change layer 24a, and the second phase change layer 24b may be formed of Ge₂Sb₂Te₅ (GST). The bottom electrode 22 and the upper electrode 26 can be formed of any conductive material that is used in a conventional memory device. For example, the bottom electrode 22 and the upper electrode 26 can be formed of a noble metal. The contact layer 25 can be formed of Ti. When the phase change memory device operates and a current is applied through the bottom electrode 22 and the upper electrode 26, a PV area 27 in which a phase change occurs is formed between the BEC layer 23 and the first phase change layer 24a.

Since the PV area 27 is formed at the interface of the BEC layer 23 and the first phase change layer 24a which are formed of the same kind of material, interface deterioration and heat loss occurring at the interface between different kinds of materials can be prevented. The phase change memory device according to the current embodiment can be an I-shape phase change memory device since the BEC layer 23, the first phase change layer 24a, and the second phase change layer 24b are formed of the same kind of phase change material.

FIG. 3 is a sectional view of a phase change memory device according to an embodiment of the present invention electrically connected to a transistor which functions as a switching device. Referring to FIG. 3, a gate insulating layer 33 contacting a source 32a and a drain 32b and a gate electrode layer 34 are formed on a semiconductor substrate 31 including the source 32a and the drain 32b. An inter-insulating layer 35 is formed on the semiconductor substrate 31 and the gate electrode layer 34 (word line). The drain 32b is electrically connected to the bottom electrode 22 of the phase change memory device illustrated in FIG. 2 through the inter-insulating layer 35.

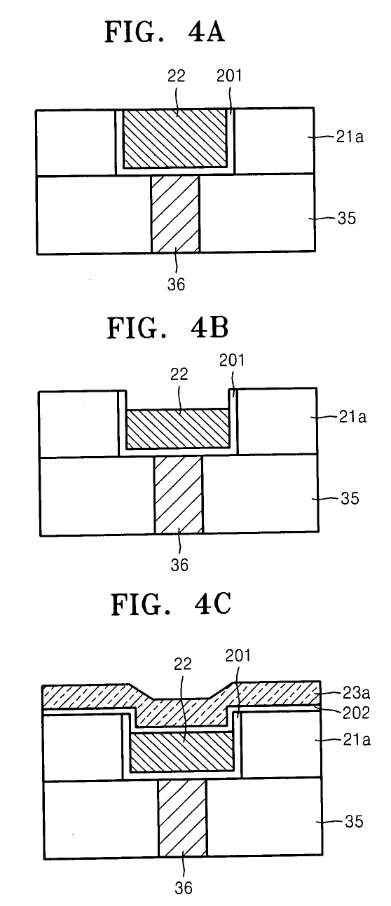

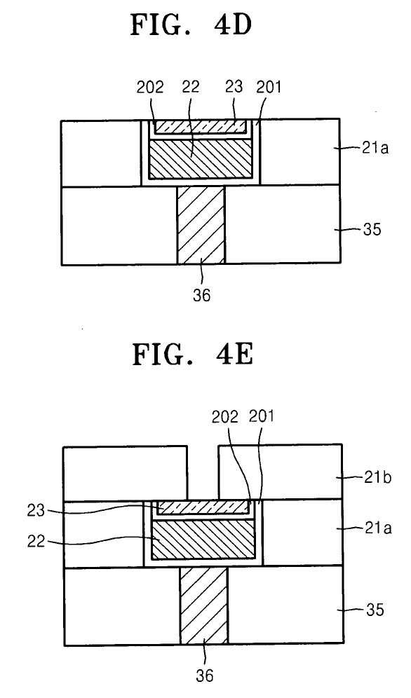

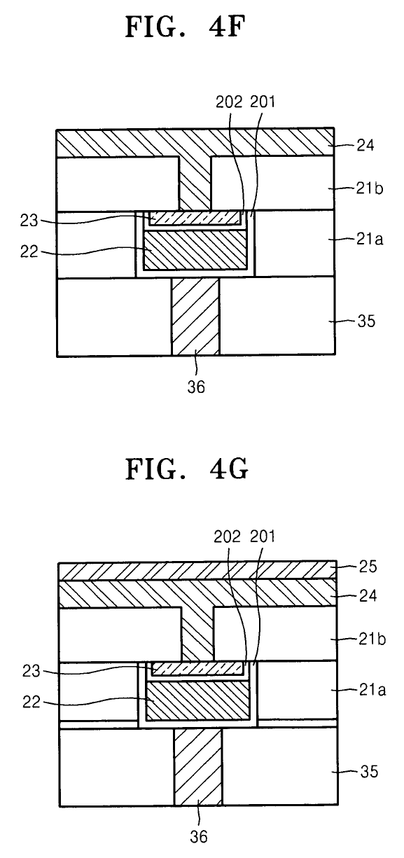

Hereinafter, a method of fabricating a phase change memory device according to an embodiment of the present invention will be described in detail with reference to FIGS. 4A through 4G. In general, diodes or transistors are fabricated using a conventional method of fabricating a semiconductor device. Herein, a method of fabricating a phase change memory device according to an embodiment of the present invention on a contact plug of a transistor structure will be described in detail.

Referring to FIG. 4A, a first insulating layer 21a is deposited on a contact plug 36 of a transistor, and a portion of the first insulating layer 21a in which a bottom electrode is to be formed is removed to expose a contact plug 36. Then, a conductive material is deposited on the exposed surface of the contact plug 36 to form a bottom electrode 22. If required, a contact pad 201 can be formed using TiN and then the bottom electrode 22 can be formed using tungsten (W), to reduce contact resistance. Then, the resultant structure is planarized by chemical mechanical polishing (CMP).

Referring to FIG. 4B, a top portion of the bottom electrode 22 in the first insulating layer 21a is dry-etched. For example, the bottom electrode 22 is formed using W and then etched to a depth of about 1.5 K□.

Referring to FIG. 4C, a phase change material 23a is deposited on the bottom electrode 22 using a metal oxide chemical deposition (MOCVD) process or an atomic layer deposition (ALD) process. If required, before the phase change material 23a is deposited, a Ti/TiN thin layer 202 can be deposited as a barrier metal (BM) layer. The phase change material 23a can be GST and a source material gas for the GST can include a 2-valent Ge-containing precursor (first precursor), a Sb-containing precursor (second precursor), and a Te-containing precursor (third precursor.) The first through third precursors are organic metal compounds, and specifically, the first precursor can be a 2-valent Ge-containing organic metal compound. The first through third precursors can be provided at the same time (MOCVD.) Alternatively, each precursor can be sequentially provided (cyclic-CVD), or two precursors can be provided at the same time (ALD.)

Referring to FIG. 4D, after the phase change material 23a is deposited, the surface of the phase change material 23a is planarized using a CMP process to form a BEC layer 23.

Referring to FIG. 4E, a second insulating layer 21b is formed by depositing an insulating material, such as SiO₂, SiON, or Si₃N₄, and then etched to form a hole therein to expose the BEC layer 23.

Referring to FIG. 4F, a phase change layer 24 is formed by depositing a phase change material, such as GST, on the second insulating layer 21b and filling the hole of the second insulating layer 21b with the phase change material. Although as illustrated in FIG. 4E, the formed second insulating layer 21b can be etched until the BEC layer 23 is exposed, the BEC layer 23 can be filled with the phase change material while the phase change layer is formed. Like the process of forming the BEC layer 23, the phase change layer 24 can be formed using a MOCVD process or an ALD process.

Referring to FIG. 4G, a top portion of the phase change layer 24 is planarized using a CMP process, and then, a conductive material is deposited thereon to form a upper electrode 25.

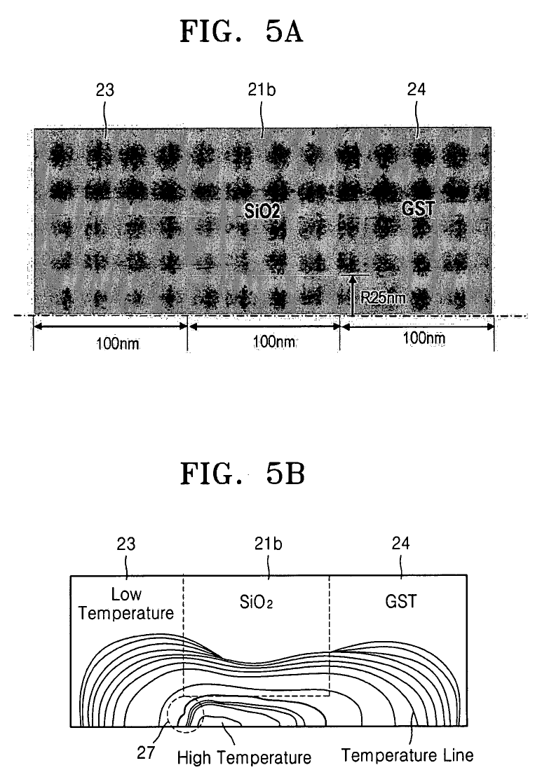

FIGS. 5A and 5B are pictorial views illustrating results of measuring temperatures of respective areas when a current is provided through bottom and upper electrodes of a phase change memory device according to an embodiment of the present invention. Specifically, FIG. 5A is an enlarged view of the dotted line area of the phase change memory device of FIG. 2, illustrating the BEC layer 23, the second insulating layer 21b, and the phase change layer 24. FIG. 5B is a pictorial view illustrating temperatures of the phase change memory device when a current is applied through upper and bottom electrodes of the phase change memory device of FIG. 5A.

Referring to FIG. 5B, it is identified that the temperature at the interface between the BEC layer 23 and the phase change layer 24 formed of GST is highest, that is, a PV area formed at the interface between the BEC layer 23 and the phase change layer 24.

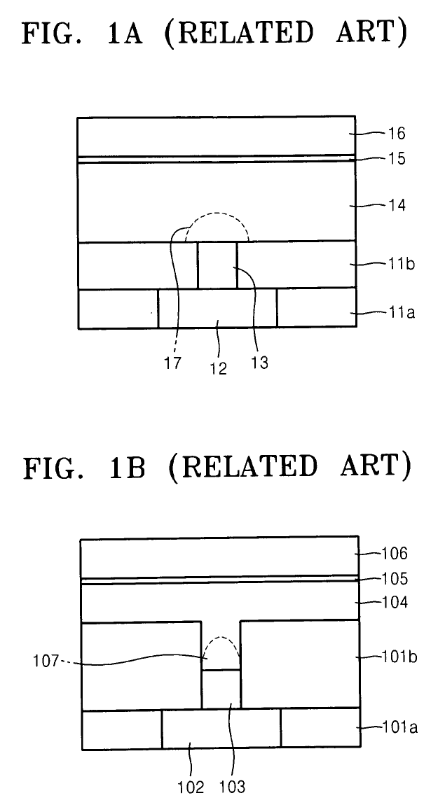

In the case of a conventional T-shaped phase change memory device as illustrated in FIG. 1A, the BEC layer 13 is usually formed of TiN or TiAlN. Such electrode materials have high thermal conductivity so that heat loss occur in a downward direction of the BEC layer 13 and thus a reset current required to operate a phase change memory device is high. However, in the case of the phase change device according to an embodiment of the present invention, the BEC layer 23 and the phase change layer 24 are formed of the same kind of phase change material so that thermal conductivity is relatively low. Accordingly, heat loss is relatively low and a reset current required can be reduced. A reset current of a conventionally shaped phase change memory device in which a BEC layer is formed of TiN is 2.04 mA, on the other hand, a reset current of a phase change memory device according to an embodiment of the present invention is 1.03 mA.

Effects of the present invention will now be described in detail.

First, deterioration at the interface between a BEC layer and a phase change layer can be prevented by forming the BEC layer and the phase change layer using the same kind of material.

Second, heat loss can be prevented more by forming the BEC using a phase change material, compared to a phase change memory device using a conventional electrode material. Accordingly, a reset current can be reduced.

Third, a PV area can be stably formed by preventing deterioration and thus a phase change memory device can have high reliability.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A phase change memory device comprising a phase change layer in a storage node thereof, the phase change memory device comprising:
a bottom electrode;
a bottom electrode contact layer formed of a phase change material disposed on the bottom electrode;
a first phase change layer having a smaller width than the bottom electrode contact layer, disposed on the bottom electrode contact layer;
a second phase change layer having a larger width than the first phase change layer, disposed on the first phase change layer; and
a upper electrode disposed on the second phase change layer.

2. The phase change memory device of claim 1, further comprising:
a first insulating layer formed on side surfaces of the bottom electrode and the bottom electrode contact layer; and
a second insulating layer formed on side surfaces of the first phase change layer.

3. The phase change memory device of claim 1, wherein the bottom electrode contact layer, the first phase change layer, and the second phase change layer are formed of the same kind of phase change material.

4. The phase change memory device of claim 1, wherein the bottom electrode contact layer, the first phase change layer, and the second phase change layer are formed of Ge₂Sb₂Te₅ (GST) that is a phase change material.

5. The phase change memory device of claim 1, wherein a program value area is formed at the interface between the bottom electrode contact layer and the first phase change layer.

6. The phase change memory device of claim 1, further comprising a Ti or TiN thin layer interposed between the bottom electrode and the bottom electrode contact layer.

7. The phase change memory device of claim 1, further comprising:
a semiconductor substrate having a source region and a drain region;
a gate insulating layer contacting one of the source region and the drain region, disposed on the semiconductor substrate;
a gate electrode layer disposed on the gate insulating layer; and
a contact plug formed between the drain region and the bottom electrode.

8. A method of fabricating a phase change memory device comprising a phase change layer in a storage node, the method comprising:
(a) opening a first insulating layer, and forming and planarizing a bottom electrode and a bottom electrode contact layer;
(b) forming a second insulating layer on the first insulating layer and the bottom electrode, and forming a hole having a smaller width than the bottom electrode to expose the bottom electrode;
(c) forming a phase change layer in the hole and on the second insulating layer;
(d) forming a upper electrode on the phase change layer.

9. The method of claim 8, wherein (a) comprises:
forming a first insulating layer;
opening the first insulating layer, and forming the bottom electrode and etching a top portion of the bottom electrode;
doping a phase change material on the bottom electrode; and
planarizing the phase change material to form a bottom electrode contact layer.

10. The method of claim 9, wherein a Ti or TiN thin layer is formed on the bottom electrode, and then doped with a phase change material.

11. The method of claim 8, wherein the bottom electrode contact layer, the first phase change layer, and the second phase change layer are formed of the same kind of phase change material.

12. The method of claim 8, wherein the bottom electrode contact layer, the first phase change layer and the second phase change layer are formed of Ge₂Sb₂Te₅ (GST) that is a phase change material.

13. The method of claim 8, wherein the phase change layer is formed using a metal oxide chemical deposition (MOCVD) process or an atomic layer deposition (ALD) process.
